(19) United States
(12) Patent Application Publication
(10) Pub. No.: US 2025/0315563 A1
(43) Pub. Date: Oct. 9, 2025

(54) SYSTEM AND METHOD FOR INTELLIGENT EVACUATION GUIDANCE BASED ON SPATIAL SOUND

(71) Applicant: Electronics and Telecommunications Research Institute, Daejeon (KR)

(72) Inventors: Seung Chul Son, Daejeon (KR); Seok Kap Ko, Daejeon (KR)

(73) Assignee: Electronics and Telecommunications Research Institute, Daejeon (KR)

(21) Appl. No.: 18/939,690

(22) Filed: Nov. 7, 2024

(30) Foreign Application Priority Data
Apr. 3, 2024 (KR) 10-2024-0045311

(51) Int. Cl. G06F 30/13; H04S 7/00

(52) U.S. Cl. CPC G06F 30/13; H04S 7/302; H04S 7/305; H04S 2400/11

(57) ABSTRACT

Provided are a spatial sound-based intelligent evacuation guidance system and method. The spatial sound-based intelligent evacuation guidance system includes a digital twin system and an evacuation guidance device. The digital twin system determines the on-site deployment of a sound reproducer and a reverberation eliminator included in the spatial sound-based evacuation guidance device based on simulation results in which a virtual human is evacuated to a destination according to evacuation guidance sound.

### CROSS-REFERENCE TO RELATED APPLICATION

This application claims priority to and the benefit of Korean Patent Application No. 10-2024-0045311, filed on Apr. 3, 2024, the disclosure of which is incorporated herein by reference in its entirety.

### BACKGROUND

### 1. Field

The present invention relates to an evacuation guidance technology using sound.

### 2. Description of Related Art

In situations where fire obstructs the field of vision, existing evacuation systems such as emergency bell equipment, automatic siren equipment, stand-alone alarm detectors, and emergency broadcasting equipment only provide alarm functions.

ExitPoint, which is Notifier's directional sound speaker that uses sound to guide evacuation, serves as an audible evacuation exit sign in situations where the path ahead cannot be identified by receiving signals from fire alarm control panels installed along the building's emergency exits or escape routes and transmitting sound in a wide range of frequencies. Because any sound in the audible range can be transmitted, occupants can know the location of the sound source, thereby providing directionality and producing a sound that is distinct from existing sound devices such as sirens or bells. However, this technology requires installing a large number of speakers throughout the entire designated area to set up the acoustic evacuation route. In particular, in modern multi-story buildings, speakers should be installed on every floor, which is a significant drawback, so there is a need for improvement.

The paper published in the Fire Safety Journal in 2021 titled “Sound signals to improve evacuation in road tunnels” disclosed the results of an experiment to evaluate whether sound signals could help people are evacuated from smoke-filled tunnels due to fire, that is, an experiment to see which sound would be more helpful for being evacuated from a tunnel among a click, a whistle, or a bell.

In addition, the paper “Evacuation Guidance Assistance System Using Emitting Sound” published in the journal Noise Control in 2022 disclosed the results of an experiment to compare the accuracy and response time of subjects in identifying sound stimuli of different sequences by combining several experimental conditions such as sound type, emission interval, distance between speakers, sequence patterns, and the like.

In addition, the paper “Study of Sound Direction Evacuation,” published in the Journal of Physics: Conference Series in 2018 disclosed the results of a performance experiment according to various frequency distributions of directional speakers in a fire alarm (siren) and ambient noise environment.

The above-mentioned conventional technologies are only basic feasibility studies, do not reach the stage of field application, and have limitations that they are insufficient as an intuitive and intelligent evacuation guidance technology to secure golden time in situations where the field of vision is short during a fire.

### SUMMARY OF THE INVENTION

The present invention is directed to providing an intelligent evacuation guidance system and method based on spatial sound, which output evacuation guidance sound to guide people to be evacuated to a safe zone or exit in situations where evacuation is difficult due to difficulty in identifying visual guidance indicators due to blocked lighting, smoke, dust, etc., during disasters like fire in multi-use underground facilities (such as subways, underground passages, tunnels, etc.).

To this end, technology for designing spatial stereoscopic sound based on digital sound standards (e.g., MPEG-H Audio or Dolby Atmos) suitable for a target space and technology for distributing a large number of people to be evacuated are applied.

The technical problem of the present invention is not limited to the points described above, and other technical problems will be clearly understood by those skilled in the art from the following description.

According to an aspect of the present invention, there is provided a spatial sound-based intelligent evacuation guidance system, which includes a digital twin system and an evacuation guidance device.

The digital twin system may include a memory configured to store computer-readable instructions, at least one processor configured to be implemented to execute the instructions; and an input interface device configured to receive simulation data including a structure of a target space, locations of one or more destinations in the target space, the number of sound reproducers, the number of reverberation eliminators, and the number of virtual humans to be deployed in a virtual space obtained by modeling the target space, wherein the at least one processor executes the instructions to set locations where the sound reproducer and the reverberation eliminator are to be deployed in the virtual space according to predetermined criteria, set an evacuation guidance sound output to be directed to the destination through the sound reproducer disposed in the virtual space, apply the simulation data, the location of the sound reproducer, the location of the reverberation eliminator, and the evacuation guidance sound to the virtual space to perform a simulation in which the virtual human is evacuated to the destination according to the evacuation guidance sound, and evaluate a result of the simulation according to predetermined evaluation criteria to determine the location of the sound reproducer and the location of the reverberation eliminator.

In one embodiment of the present invention, the simulation data may further include information on finishing materials for a wall, a ceiling, and a floor of the target space.

In one embodiment of the present invention, the at least one processor may randomly deploy the virtual human in the virtual space, and then perform the simulation.

In one embodiment of the present invention, the evaluation criteria may include a time at which all the virtual humans arrive at the destination.

In one embodiment of the present invention, the at least one processor may determine whether there are a plurality of destinations, the input interface device may receive a predetermined distribution policy for a person to be evacuated in the case of the plurality of destinations, and the at least one processor may reflect the distribution policy for the person to be evacuated when the evacuation guidance sound is set and then perform the simulation.

In one embodiment of the present invention, in the distribution policy for the person to be evacuated, the target space may be divided into a plurality of zones based on the location of the destination and different evacuation guidance sounds may be applied according to the zones.

In one embodiment of the present invention, in the distribution policy for the person to be evacuated, a weight may be assigned to each of the plurality of destinations, and an output time of the evacuation guidance sound directed to each of the destinations may be determined based on the weight.

In one embodiment of the present invention, in the distribution policy for the person to be evacuated, a weight may be assigned to each of the plurality of destinations, and an output frequency of the evacuation guidance sound directed to each of the destinations may be determined based on the weight.

In one embodiment of the present invention, the evacuation guidance sound may be configured by combining sound flows according to at least one type of linear sound flow, planar sound flow, and spatial sound flow between a plurality of sound reproducers.

In one embodiment of the present invention, the at least one processor may be configured to perform the simulation a plurality of times and change the locations of the sound reproducer and the reverberation eliminator before performing the simulation.

In one embodiment of the present invention, the at least one processor may be configured to perform the simulation a plurality of times and change the locations of the sound reproducer and the reverberation eliminator before performing the simulation.

An evacuation guidance device according to one embodiment of the present invention may include a communication device, a spatial sound generator, a sound reproducer, and a reverberation eliminator. The communication device may transmit and receive data to and from a digital twin system. The spatial sound generator may generate spatial sound such as stereoscopic sound or sequential sound to guide evacuation. The sound reproducer may output the spatial sound generated by the spatial sound generator toward the target space. The reverberation eliminator may cancel out reflected sound generated by finishing materials such as walls, ceiling, and structures in the target space using active noise control (ANC) technology.

According to another aspect of the present invention, there is provided a spatial sound-based intelligent evacuation guidance method, which includes receiving, by a digital twin system, simulation data including a structure of a target space, locations of one or more destinations in the target space, the number of sound reproducers, the number of reverberation eliminators, and the number of virtual humans to be deployed in a virtual space obtained by modeling the target space; setting, by the digital twin system, locations where the sound reproducer and the reverberation eliminator are to be deployed in the virtual space according to predetermined criteria; setting, by the digital twin system, an evacuation guidance sound output to be directed to the destination through the sound reproducer disposed in the virtual space; applying, by the digital twin system, the simulation data, the location of the sound reproducer, the location of the reverberation eliminator, and the evacuation guidance sound to the virtual space to perform a simulation in which the virtual human is evacuated to the destination according to the evacuation guidance sound; and evaluating, by the digital twin system, the result of the simulation according to predetermined evaluation criteria to determine the location of the sound reproducer and the location of the reverberation eliminator.

In one embodiment of the present invention, the simulation data may further include information on finishing materials for walls, a ceiling, and a floor of the target space.

In one embodiment of the present invention, the performing of the simulation may include randomly deploying, by the digital twin system, the virtual human in the virtual space, and then perform the simulation.

In one embodiment of the present invention, the evaluation criteria may include a time at which all the virtual humans arrive at the destination.

In one embodiment of the present invention, the intelligent evacuation guidance method based on spatial sound may further include determining, by the digital twin system, whether there are a plurality of destinations, and receiving, in the case of the plurality of destinations, a predetermined distribution policy for a person to be evacuated.

In one embodiment of the present invention, the performing of the simulation may include performing the simulation after reflecting the distribution policy for the person to be evacuated in the setting of the evacuation guidance sound.

In one embodiment of the present invention, in the distribution policy for the person to be evacuated, the target space may be divided into a plurality of zones based on the location of the destination and different evacuation guidance sounds may be applied according to the zones.

In one embodiment of the present invention, in the distribution policy for the person to be evacuated, a weight may be assigned to each of the plurality of destinations, and an output time of the evacuation guidance sound directed to each of the destinations may be determined based on the weight.

In one embodiment of the present invention, in the distribution policy for the person to be evacuated, a weight may be assigned to each of the plurality of destinations, and an output frequency of the evacuation guidance sound directed to each of the destinations may be determined based on the weight.

In one embodiment of the present invention, the evacuation guidance sound may be configured by combining sound flows according to at least one type of linear sound flow, planar sound flow, and spatial sound flow between a plurality of sound reproducers.

In one embodiment of the present invention, the performing of the simulation may be performed a plurality of times.

In one embodiment of the present invention, the intelligent evacuation guidance method based on spatial sound may further include changing, by the digital twin system, the locations of the sound reproducer and the reverberation eliminator.

The above-described configurations and operations of the present invention will become more apparent from embodiments described in detail below with reference to the accompanying drawings.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram illustrating a configuration of an intelligent evacuation guidance system based on spatial sound according to an embodiment of the present invention;

FIG. 2 is a schematic diagram illustrating an evacuation guidance device based on spatial sound according to one embodiment of the present invention;

FIG. 3 is a diagram illustrating an embodiment of guiding evacuation of people to be evacuated based on sequential sound;

FIG. 4 is a diagram illustrating an example of spatial sound design using an intelligent evacuation guidance system according to an embodiment of the present invention;

FIG. 5A to 5C are diagrams illustrating examples of types of sound flow;

FIGS. 6A and 6B are diagrams illustrating user input elements for automatic sound flow design;

FIG. 7 is a diagram illustrating a spatial sound evacuation guidance test using a digital twin system according to an embodiment of the present invention;

FIG. 8 is a diagram illustrating the concept of dividing a target space for distributed evacuation and optimal evacuation direction guidance;

FIG. 9 is a diagram illustrating the concept of time-space division of spatial sound for distributed evacuation;

FIG. 10 is a diagram illustrating a large-scale virtual human simulation test using a digital twin system according to one embodiment of the present invention;

FIG. 11 is a diagram illustrating an example of the installation of a spatial sound-based evacuation guidance device combined with a visual evacuation guidance device; and

FIG. 12 is a flowchart illustrating an intelligent evacuation guidance method based on spatial sound according to one embodiment of the present invention.

### DETAILED DESCRIPTION OF EXEMPLARY EMBODIMENTS

The present invention relates to evacuation guidance technology using sound. Specifically, the present invention relates to a system and method for guiding evacuation of people to be evacuated based on spatial sound in response to a disaster. For example, when a fire occurs in an underground facility or a multi-use facility, the present invention can be used to provide intuitive evacuation guidance sound to people to be evacuated through spatial stereophonic sound in situations where the field of vision is not secured due to smoke.

The advantages and features of the present disclosure and methods therefor will become apparent with reference to the embodiments described below in detail in conjunction with the accompanying drawings. However, the present disclosure is not limited to the embodiments disclosed below, and may be implemented in various different forms. The present embodiments are provided only to ensure the disclosure of the present specification is completed and to completely inform those of ordinary skill in the art of this specification the scope of the present invention, and the specification will be defined by the scope of the claims. Meanwhile, terms used in the present specification are used only in order to describe specific exemplary embodiments rather than limiting the present invention. In the present specification, singular forms are intended to include plural forms unless the context clearly indicates otherwise. The terms “comprise” and “have” used in this specification, specify the presence of stated features, numerals, steps, operations, components, parts, or a combination thereof, but do not preclude the presence or addition of one or more other features, numerals, steps, operations, components, parts, or a combination thereof.

Terms such as “first,” and/or “second,” etc., may be used to describe various components, but the components are not to be construed as being limited to the terms. The terms are used only to distinguish one component from another component. For example, a “first” component may be called a “second” component and a “second” component may also be similarly called a “first” component without departing from the scope of the present invention.

It is to be understood that when a first component is referred to as being “connected to” or “coupled to” a second element, it may be connected or coupled directly to the second element or be connected to or coupled to the second element with a third element intervening therebetween. On the other hand, it is to be understood that when a first element is referred to as being “connected directly to” or “coupled directly to” a second element, it may be connected or coupled to the second element with no other element intervening therebetween. Other expressions describing a relationship between components, such as “between,” “directly between,” “neighboring,” “directly neighboring,” and the like, should be similarly interpreted.

In describing the present invention, when it is determined that a detailed description of related known technology may unnecessarily obscure the gist of the present invention, the detailed description will be omitted.

Hereinafter, embodiments of the present invention will be described in detail with reference to the attached drawings. In order to facilitate overall understanding in describing the present invention, the same reference numbers will be used for the same means regardless of the drawing numbers.

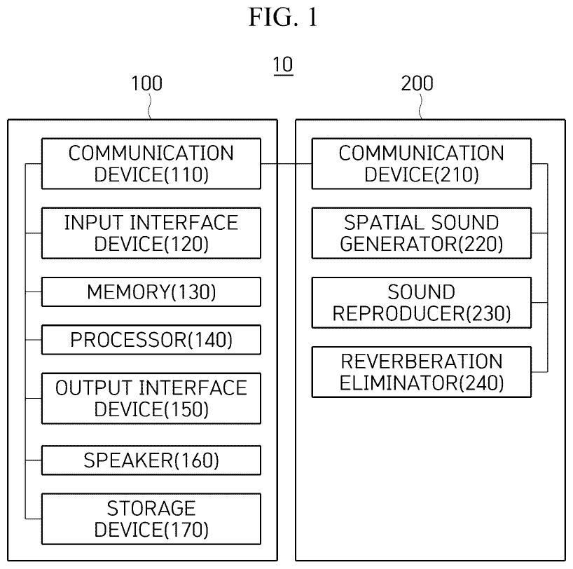

FIG. 1 is a block diagram illustrating a configuration of an intelligent evacuation guidance system based on spatial sound according to an embodiment of the present invention.

A spatial sound-based intelligent evacuation guidance system 10 according to an embodiment of the present invention includes a digital twin system 100 and a spatial sound-based evacuation guidance device 200 (hereinafter referred to as “evacuation guidance device”).

The intelligent evacuation guidance system 10 is a multi-speaker and stereophonic sound system that simultaneously generates flows of sound (hereinafter referred to as “evacuation guidance sound”) to guide people to be evacuated to destinations such as exits or safe zones by utilizing various sound effects representing the forward/backward, left/right, up/down movement of the sound, such as volume, reverb, pan, and frequency in situations where the field of vision of the people to be evacuated is not secured during a disaster (e.g., fire).

The digital twin system 100 may model a virtual space and perform spatial and sound digital twin simulations to find and design an optimal guidance sound toward the evacuation destination. In addition, the digital twin system 100 utilizes the digital twin simulation to perform a simulation test of real-virtual human connection that guides the evacuation of actual people whose the field of vision is obstructed and a large-scale virtual human simulation test where virtual humans having imitated human's auditory senses are massively deployed in the virtual space to test the guidance of distributing virtual humans towards multiple evacuation destinations. The digital twin system 100 may utilize the digital twin simulation to select the optimal evacuation sound, optimal deployment of a sound reproducer 230, and optimal deployment of a reverberation eliminator 240.

The digital twin system 100 may be implemented in the form of a computer system as shown in FIG. 1. Referring to FIG. 1, the digital twin system 100 includes a communication device 110, an input interface device 120, a memory 130, a processor 140, an output interface device 150, a speaker 160, and a storage device 170. The components of the digital twin system 100 according to the present invention are not limited to the embodiment shown in FIG. 1, and may be added, changed, or deleted as necessary.

The communication device 110 may be coupled to a wired/wireless network and transmit or receive wired or wireless signals. The communication device 110 transmits and receives data to and from a communication device 210 of the evacuation guidance device 200 through the wired or wireless network.

The processor 140 may be a central processing unit (CPU) or a semiconductor device that executes instructions stored in the memory 130 or the storage device 170.

The memory 130 or the storage device 170 may include various types of volatile or non-volatile storage media. For example, the memory 130 may include a read only memory (ROM) and a random access memory (RAM). In this embodiment, the memory 130 may be located inside or outside the processor 140, and the memory 130 may be connected to the processor 140 through various known means. The memory 130 is various types of volatile or non-volatile storage media. For example, the memory 130 may include a ROM or RAM.

The input interface device 120 may be an input device such as a keyboard or joystick, and the output interface device 150 may be a display device.

Embodiments of the present invention may be implemented as a computer-implemented method or as a non-transitory computer-readable medium storing computer-executable instructions. In one embodiment, when executed by a processor, a method according to at least one aspect of the present disclosure may be performed through computer-readable instructions.

In addition, the method according to one embodiment of the present invention may be implemented in the form of program instructions that can be executed through various computer means and recorded on a computer-readable medium.

The computer-readable medium may include a program instruction, a data file, a data structure, or the like, or a combination thereof. The program instruction recorded in the computer-readable medium may be specially designed and configured for an exemplary embodiment of the present invention, or may be known and used by a person skilled in the field of computer software. A computer-readable recording medium may include a hardware device configured to store and perform program instructions. For example, the computer-readable recording medium exemplarily includes magnetic media such as hard disks, floppy disks, and magnetic tapes; optical media such as compact disk-read only memories (CD-ROMs) and digital versatile disks (DVDs); magneto-optical media such as floptical disks; and hardware devices such as a ROM, a RAM, and a flash memory, which are specially configured to store and execute program instructions. Examples of the program instructions include not only machine language codes created by a compiler or the like, but also high-level language codes that can be executed by a computer using an interpreter or the like.

The evacuation guidance device 200 is a device to prepare for disasters that may occur in the future by applying the deployment plan (layout) of the sound reproducer 230 and the reverberation eliminator 240 derived from the results (simulation test results) of the digital twin simulation in the digital twin system 100 to the field. The above deployment plan may be applied to the field automatically or manually. For example, the deployment plan of the sound reproducer 230 and the reverberation eliminator 240 may be applied to the field through a method in which the sound reproducer 230 or the reverberation eliminator 240 automatically moves through rails installed on the wall of a targeted space (may be referred to as ‘target space’) or may be applied to the field manually through construction or detachment.

Referring to FIG. 1, the evacuation guidance device 200 includes the communication device 210, a spatial sound generator 220, the sound reproducer 230, and the reverberation eliminator 240. The components of the evacuation guidance device 200 according to the present invention are not limited to the embodiment shown in FIG. 1, and may be added, changed, or deleted as necessary.

The communication device 210 transmits and receives data to and from the communication device 110 of the digital twin system 100.

The spatial sound generator 220 generates spatial sound such as stereoscopic sound or sequential sound. The spatial sound generator 220 has a built- in processor and controls the sound reproducer 230.

The sound reproducer 230 may be a high-performance multi-channel speaker as a device that outputs spatial sound generated by the spatial sound generator 220 toward the target space.

The reverberation eliminator 240 is a device that cancels out reflected sound generated by finishing materials such as walls, ceilings, and structures of the target space using active noise control (ANC) technology, etc. The reverberation eliminator 240 may be manufactured as an integrated unit combined with the sound reproducer 230.

The evacuation guidance device 200 may include a plurality of sound reproducers 230 and a plurality of reverberation eliminators 240.

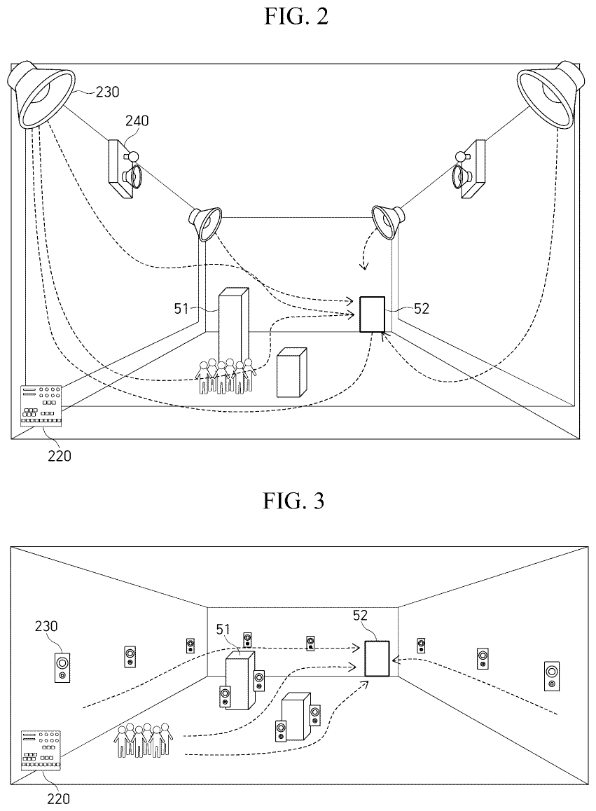

FIG. 2 is a schematic diagram illustrating an evacuation guidance device based on spatial sound according to one embodiment of the present invention. FIG. 2 shows the evacuation guidance device 200 actually deployed in the target space. That is, the spatial sound generator 220, the sound reproducer 230, and the reverberation eliminator 240 are installed in the target space of FIG. 2. In addition, the target space in FIG. 2 includes a wall, a ceiling, a structure 51, and a destination 52, which is a point for evacuation.

In this specification, the “target space’ refers to a space targeted by the spatial sound-based intelligent evacuation guidance system 10 according to the present invention, and refers to a space where people to be evacuated are located during a disaster. The target space may be the interior space of a building visited by many people. For example, the target space may be a subway station, underground parking lot, department store, mart, etc. When a fire occurs in the target space, smoke cannot escape and it is difficult to secure the field of vision for people to be evacuated, so visual evacuation guidance technology may have limitations. Therefore, when the field of vision is not sufficient, the people to be evacuated may be guided to move to a destination (52, e.g., exit, safety zone, shelter) using the evacuation guidance sound output by the evacuation guidance device 200 according to the present invention. The spatial sound generator 220 is a professional audio mixer and is a device that generates various sound sources and controls the sound reproducer 230 to impart spatiality and directionality to the evacuation guidance sound. That is, the spatial sound generator 220 is a device that can generate flow in the sound through horizontal and vertical surround sound techniques (spatial audio) and generates evacuation guidance sound that flows towards the destination 52 within the target space.

The sound reproducer 230 may be a multi-channel speaker and is a high-performance speaker for reproducing the moving sound (evacuation guidance sound) generated by the spatial sound generator 220. The people to be evacuated in the target space can hear evacuation guidance sound moving to the destination 52 through the sound reproducer 230.

The reverberation eliminator 240 is a device that removes reflected sound generated by finishing materials such as walls, ceilings, and structures of the target space, and may be an electronic sound absorber. In reality, in order to accurately reproduce the movement of sound, the exterior walls of the target space should be sound-absorbing materials, but when the entire space is constructed with sound-absorbing materials, large costs are incurred. Accordingly, the reverberation eliminators 240 utilizing general active noise cancellation (ANC) technology are used to remove as much reverberation as possible reflected from the walls, thereby enhancing the clarity of the moving sound (evacuation guidance sound). The reverberation eliminator 240 may include a microphone that collects and distinguishes the reverberations reflected from the walls and a speaker that emits opposite-phase sound waves for each distinguished reverberation. Since various reverberations will reach the microphone due to reflectors such as walls, ceilings, and structures, distinguishing these reverberations is necessary to generate and emit the opposite-phase sound waves through the speaker. To this end, the reverberation eliminator 240 may include a controller that distinguishes the frequency, amplitude, and phase of each reverberation and generates opposite-phase sound waves accordingly.

FIG. 3 is a diagram illustrating an embodiment of guiding evacuation of people to be evacuated based on sequential sound.

The evacuation guidance device 200 may guide people to be evacuated through sequential speaker output (sequential sound) in a state where the evacuee's the field of vision is not secured during a fire through the deployment of sequential speakers as shown in FIG. 3. At this time, the sound reproducer 230 may be composed of a plurality of speaker sets that output sound (e.g., clicks, beeps) that minimize reverberation and the Doppler effect.

The evacuation guidance device 200 may appropriately mix the stereoscopic sound described in FIG. 2 and the sequential sound in FIG. 3 according to the structure of the target space (e.g., a building). Ultimately, the stereoscopic sound and sequential sound play the role of intuitively guiding people to exits or safe zones through sound in situations where the field of vision is short due to disasters such as fire. To appropriately deploy the multiple speakers included in the sound generator 230 that output stereoscopic sound and/or sequential sound to guide evacuation, design according to the structure of the target space should be preceded. The actual target space may not be as simple as that of FIG. 2 or 3 and can be significantly more complex.

Directly deploying or modifying and optimizing the sound generator 230 and the reverberation eliminator 240 in the actual target space may incur significant costs. Therefore, digital twin-based simulation technology, which will be described later, is required.

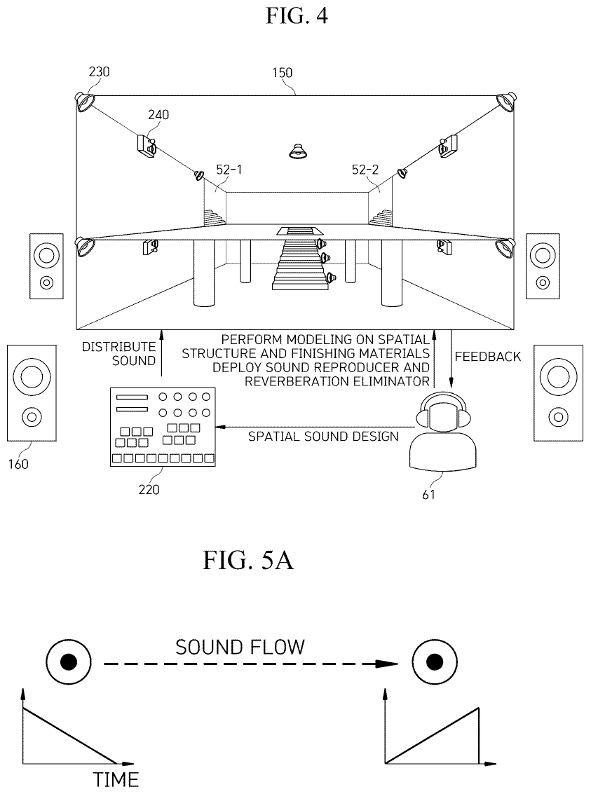

FIG. 4 is a diagram illustrating an example of spatial sound design using an intelligent evacuation guidance system according to an embodiment of the present invention.

First, the digital twin system 100 models the target space based on a user's input for spatial sound design. The virtual space in which the target space is modeled is required to have the same structure as the actual target space as much as possible, and the characteristics of finishing materials such as walls, floors, and ceilings, which greatly affect the reverberation of sound, are required to be reflected. That is, the user inputs the structure and finishing material information of the target space into the digital twin system 100 through the communication device 110 or the input interface device 120.

Next, the virtual sound reproducer 230 and the reverberation eliminator 240 are deployed in the virtual space, and evacuation guidance sound is designed. Specifically, the user inputs deployment information of the sound reproducer 230 and the reverberation eliminator 240 through the communication device 110 or the input interface device 120, and the processor 140 automatically or manually derives an optimal deployment plan (the number and location) of the sound reproducer 230 and the reverberation eliminator 240 and optimal evacuation guidance sound (sound and pattern that provides the highest clarity), based on the structure and finishing material information of the target space and the deployment information of the sound reproducer 230 and the reverberation eliminator 240. As described above, the evacuation guidance sound is sound that moves from any point in the target space to a destination 52-1 or 52-2.

The output interface device 150 of the digital twin system 100 provides visual results, such as the structure and finishing materials of the virtual space, to the user or a spatial sound designer 61.

The processor 140 may derive spatial sound (evacuation guidance sound) or reproduce the spatial sound in a virtual space by executing commands (software) stored in the memory 130 or the storage device 170. As another example, a separate spatial sound designer (not shown) made of hardware may be included in the digital twin system 100 to design and reproduce evacuation guidance sound.

In addition, the digital twin system 100 may include a headphone (not shown) or the speaker 160 to provide feedback to the spatial sound designer 61.

The spatial sound (evacuation guidance sound) may be designed either through a direct design method in which the spatial sound designer 61 (acoustic expert or someone with design experience) intuitively designs the spatial sound, or through an automatic design method in which the processor 140 automatically interprets the structure and sound of the space and designs the spatial sound accordingly.

In the case of the direct design method, the spatial sound designer 61 may modify the structure of the virtual space and deploy the virtual sound reproducer 230 and the reverberation eliminator 240 in various forms in the virtual space. Next, the spatial sound designer 61 uses the digital twin system 100 to produce and apply a variety of evacuation guidance sound moving to the destinations 52-1 and 52-2, and uses the digital twin system 100 to produce and apply various evacuation guidance sounds through the headphone or the speaker 160, receives feedback through the headphone or the speaker 160, and based on this, retrieves the optimal deployment plan (the number and location) of the sound reproducer 230 and the reverberation eliminator 240 and the optimal evacuation guidance sound.

In the case of the automatic design method, a series of direct design methods are automated through analysis of the structure and sound signals of the target space. The processor 140 may automatically arrange a number and locations of the virtual sound reproducers 230 and the reverberation eliminators 240 in various configurations in the virtual space by using a genetic algorithm based on the structure and finishing material information of the target space previously input by the user, and automatically generate the optimal deployment plan of the sound reproducer 230 and the reverberation eliminators 240 and the optical evacuation guidance sound based on the analysis of the sound signal. In this process, the user of the digital twin system 100 or the spatial sound designer 61 may intervene to limit the number or spacing of the reverberation eliminators 240 and the sound reproducers 230. The processor 140 may transmit the deployment plan of the sound reproducer 230 and the reverberation eliminator 240 and the optimal evacuation guidance sound to the communication device 210 of the evacuation guidance device 200 through the communication device 110, and the evacuation guidance device 200 may change the locations of the sound reproducer 230 and the reverberation eliminator 240 through a separately provided controller and movement device. As another example, the controller may be mounted on the spatial sound generator 220, and the spatial sound generator 220 may control the movement device to change the locations of the sound reproducer 230 and the reverberation eliminator 240. In addition, the spatial sound generator 220 may provide the sound reproducer 230 with the same sound or a modulated sound as the optimal evacuation guidance sound, so that the spatial sound that guidances evacuation is reproduced accordingly.

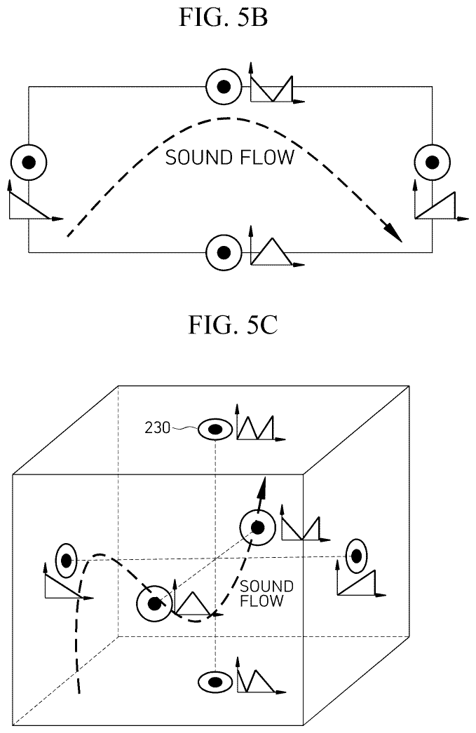

FIGS. 5A to 5C are diagrams illustrating examples of types of sound flow. FIGS. 5A to 5C show a sound flow generation method applied when evacuation guidance sound is designed. In order to reproduce the flow of sound, a plurality of sound reproducers 230 are required.

Linear sound flow (see FIG. 5A) is the most basic sound flow. In FIG. 5A, two sound reproducers 230 operate to generate a linear sound flow, and the two sound reproducers 230 implement a linear sound flow by synchronously adjusting the volume, pan, reverb, and frequency amounts in inverse proportion to each other over time.

When the sound reproducer 230, which is a unit reproduction device, is deployed in four directions, a planar sound flow may be generated (see FIG. 5B), and when the sound reproducer 230 is deployed in six directions, a spatial sound flow may be generated (see FIG. 5C). The planer sound flow may be generated by adjusting the volume, pan, reverb, frequency, etc., of the four speakers at the same time, and the spatial sound flow may be generated by adjusting the volume, pan, reverb, frequency, etc., of six speakers at the same time. Since the target space in the real world can have various forms and scales of complexity, during actual simulation and on-site device installation, it is necessary to design the optimal evacuation guidance sound by combining linear, planar, and spatial sound flow device units suitable for the complex structure.

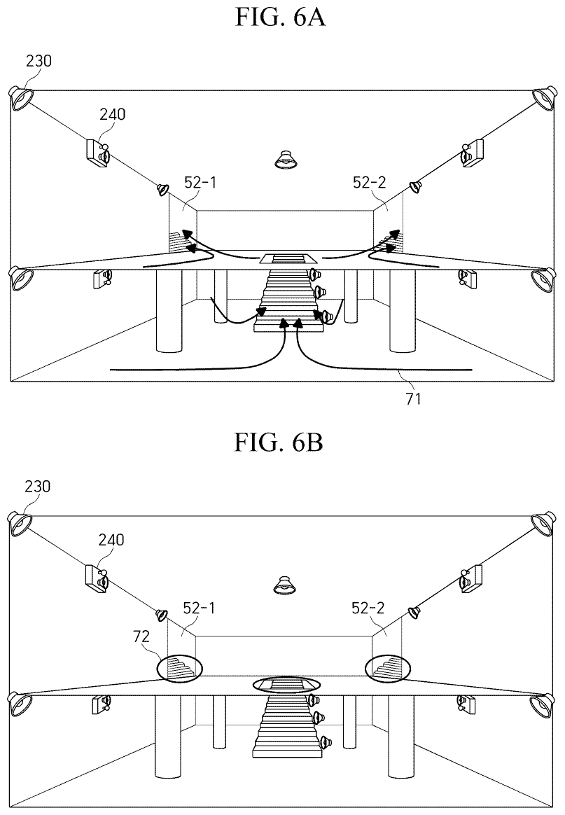

FIGS. 6A and 6B are diagrams illustrating user input elements for automatic sound flow design. FIGS. 6A and 6B show an example in which, in order to automatically design evacuation guidance sound after a digital twin for the target space is generated, a user (related person) or a space sound designer (expert) inputs an evacuation route or designation information through the input interface device 120.

In a first example, as shown in FIG. 6A, when a user or the like draws a straight or curved evacuation route 71 on a digital twin space (virtual space) through the input interface device 120, the processor 140 may generate the deployment plan of the sound reproducer 230 and the reverberation eliminator 240 to form an optimal sound flow in consideration of the input evacuation route 71 information.

In a second example, as shown in FIG. 6B, when a user or the like displays the destinations 52-1 and 52-2 as dots or planes 72, the processor 140 generates the deployment plan of the sound reproducer 230 and the reverberation eliminator 240 to form a sound flow from all points in the target space to the destinations 52-1 and 52-2 based on the input destination information.

After the deployment of the on-site devices 230 and 240, the processor 140 uses sound signal analysis according to the structure of the target space to determine the type of sound flow (linear, planar, spatial types) of the evacuation guidance sound to be applied for each zone of the target space, and determines the pattern of sound effects (volume, pan, reverb, frequency) of each sound reproducer 230 suitable for the target space in order to generate the determined sound flow.

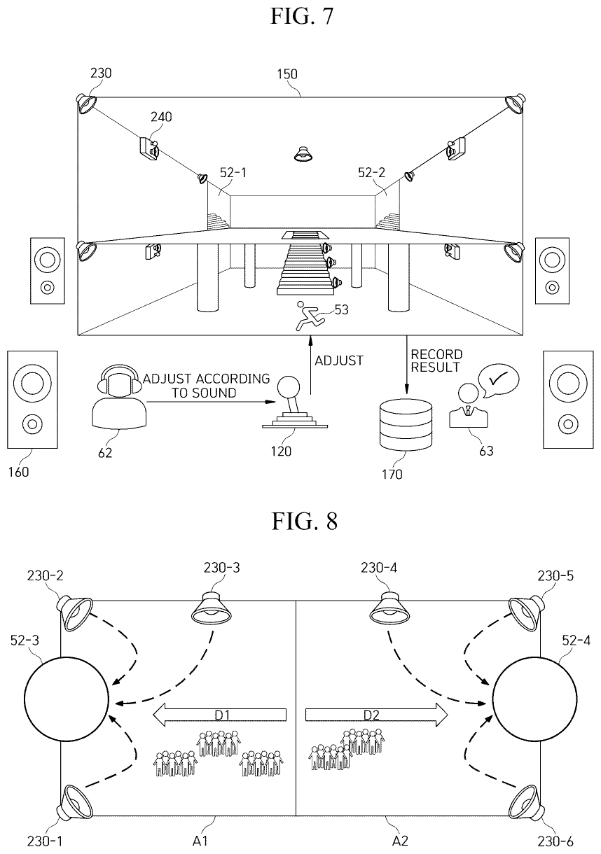

FIG. 7 is a diagram illustrating a spatial sound evacuation guidance test using a digital twin system according to an embodiment of the present invention.

Through the digital twin system 100, it is possible to test the optimal number and location of the sound reproducers 230 and reverberation eliminators 240 and the design results of the evacuation guidance sound, and this test method is shown in FIG. 7.

First, a virtual human 53 connected to a real human 62 (hereinafter referred to as ‘tester’) is deployed at any location in the virtual space, which is a model of the target space. The tester 62 controls the virtual human 53 through the input interface device 120. For example, the tester 62 may move the virtual human 53 in virtual space through the input interface device 120 while adjusting the walking or running speed of the virtual human 53.

When pre-designed evacuation guidance sound (see FIG. 4) is reproduced, the blindfolded tester 62 moves the virtual human 53 in the virtual space using the input interface device 120 along the flow of the sound. The processor 140 changes the location of the virtual human 53 in the virtual space based on an input signal received from the input interface device 120, and determines whether the virtual human 53 arrives at the destinations 52-1 and 52-2. As another example, an observer 63 may be specifically provided to determine whether the virtual human 53 arrives at the destination 52-1 or 52-2. This test method may be applied to multiple testers 62, and the processor 140 may record all movement data of the virtual human 53 input by the input interface device 120 in the storage device 170. The recorded data may later be used for training a behavior prediction model of virtual humans based on artificial intelligence in the future. For example, the behavior prediction model may be implemented using an artificial neural network.

FIG. 8 is a diagram illustrating the concept of dividing a target space for distributed evacuation and optimal evacuation direction guidance. Applying this concept to the embodiment of the present invention has the effect of minimizing human damage.

According to an embodiment of the present invention, in the evacuation guidance device 200, the sound reproducer 230 spatially divides and transmits evacuation guidance sound to distribute a large number of people to be evacuated to multiple safety zones. FIG. 8 shows an example of spatially dividing and transmitting such evacuation guidance sound.

The target space is divided into a plurality of zones A1 and A2 according to the settings. The sound reproducer 230 installed in each zone transmits evacuation guidance sound so that the sound can flow to designated destinations 52-3 and 52-4 for the zone. FIG. 8 shows directions D1 and D2 moving towards each destination 52-3 and 52-4. When a disaster occurs in the target space shown in FIG. 8, people to be evacuated present in a first zone A1 may hear the evacuation guidance sound transmitted by the sound reproducers 230-1, 230-2, and 230-3 to allow the evacuation guidance sound to flow in the direction of a first destination 52-3, and determine the evacuation direction towards the destination 52-3 for evacuation. Similarly, the people to be evacuated present in a second zone A2 may hear the evacuation guidance sound transmitted by the sound reproducers 230-4, 230-5, and 230-6 to allow the evacuation guidance sound to flow in the direction of a second destination 52-4, and determine evacuation towards the corresponding direction.

The evacuation guidance device 200 according to the embodiment of the present invention guides the people to be evacuated to move to the nearest or optimal evacuation location from the place where he or she is located through an evacuation sound transmission function to which the space division concept is applied, thereby achieving the effect of distributing the number of people to be evacuated.

FIG. 9 is a diagram illustrating the concept of time-space division of spatial sound for distributed evacuation.

A method of guiding distributed evacuation of large-scale people to be evacuated proposed in the present invention is a method in which the sound reproducer 230 simultaneously implements space division and time division to transmit evacuation guidance sound, as shown in FIG. 9. Basically, the sound reproducer 230 may sequentially transmit evacuation guidance sound aimed at multiple destinations 52-5, 52-6, and 52-7 with a time difference. At this time, a weight can be applied to the transmission frequency. For example, when it is assumed that the first destination 52-5 is a safety zone for accommodating a small number of people, the second destination 52-6 is a safety zone for accommodating a medium number of people, and the third destination 52-7 is a safety zone for accommodating a large number of people, the spatial sound generator 220 may control the length (temporal length) or transmission frequency of the evacuation guidance sound transmitted by the sound reproducer 230 in proportion to the scale that each safety zone can accommodate. Specifically, the spatial sound generator 220 controls the sound reproducer 230 to allow evacuation guidance sound S1 having the first destination 52-5, which is the safety zone for accommodating a small number of people, to be transmitted at a relatively low frequency or for a short period of time, controls the sound reproducer 230 to allow evacuation guidance sound S2 having the second destination 52-6, which is the safety zone for accommodating a medium number of people, to be transmitted at a medium frequency or for a medium period of time, and controls the sound reproducer 230 to allow evacuation guidance sound S3 having the third destination 52-7, which is the safety zone for accommodating a large number of people, to be transmitted at a relatively high frequency or for a long period of time. The control pattern of the spatial sound generator 220 described above may be determined by simulation results of the digital twin system 100 or user settings. For example, the digital twin system 100 may determine the frequency or reproduction time of each evacuation guidance sound for a plurality of destinations in the design of the evacuation guidance sound described with reference to FIG. 4.

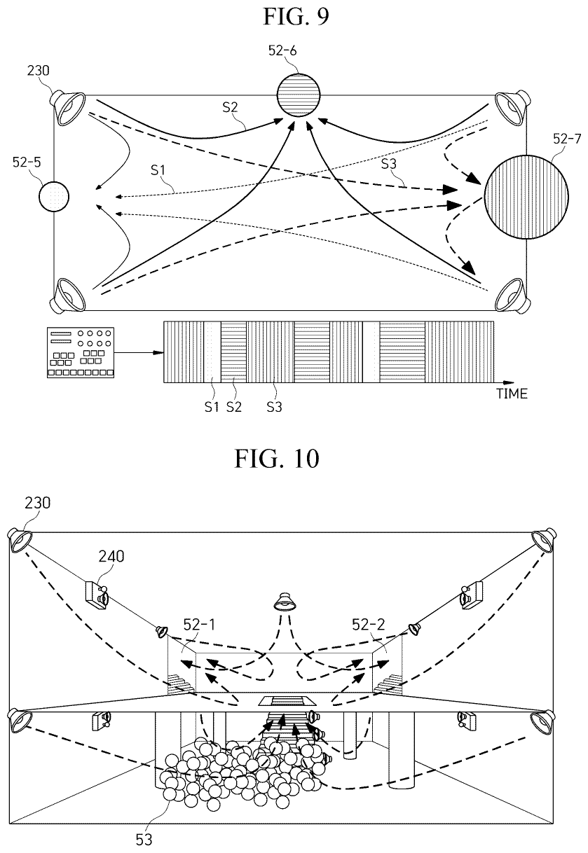

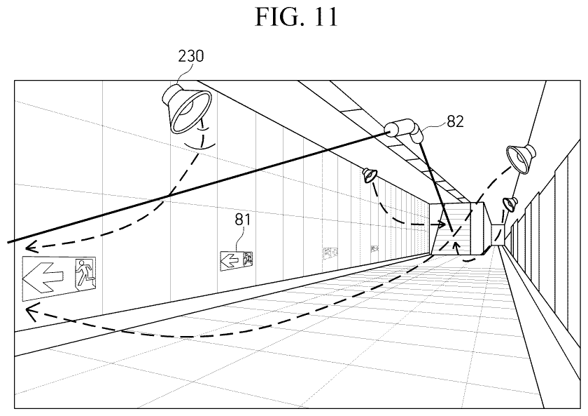

FIG. 10 is a diagram illustrating a large-scale virtual human simulation test using a digital twin system according to one embodiment of the present invention.

Before installing the evacuation guidance device 200 on site, a large-scale virtual human simulation test may be conducted using the digital twin system 100. First, as shown in FIG. 10, the processor 140 deploys a plurality of virtual humans 53 in a virtual space where a target space is modeled, and transmits the designed evacuation guidance sound. Here, the virtual human 53 is an object having an imitated human's auditory sense and is set to move along the evacuation guidance sound. The processor 140 performs a simulation test to check whether a plurality of virtual humans 53 are appropriately distributed according to the evacuation guidance sound directed to the first destination 52-1 and the second destination 52-2 and arrive at each destination 52-1 and 52-2. In order to find an optimal evacuation guidance sound solution, the processor 140 analyzes whether people to be evacuated are appropriately distributed and evacuated to each destination (for example, the number of virtual humans evacuated to a destination compared to the destination's capacity, distribution of virtual humans evacuated for each destination, etc.), the time it takes for all virtual humans to travel to their destinations (travel time), and the like while iteratively performing a series of simulation tests ranging from acoustic design to large-scale virtual human simulation. The processor 140 derives an optimal solution (the number and deployment of sound reproducers 230 and the reverberation eliminators 240, evacuation guidance sound, type of sound flow, division of target space, time-space division of evacuation guidance sound) based on the analysis results, and transmits the optimal solution to the evacuation guidance device 200. The evacuation guidance device 200 prepares for disasters that may occur in the future by applying the deployment of the devices 230 and 240, the evacuation guidance sound, and the distribution policy for people to be evacuated according to the optimal solution.

FIG. 11 is a diagram illustrating an example of the installation of a spatial sound-based evacuation guidance device combined with a visual evacuation guidance device.

The evacuation guidance device 200 according to the present invention may be combined with visual evacuation guidance equipment to further increase the evacuation effect. FIG. 11 shows an example in which an evacuation guidance light 81, an evacuation guidance laser 82, and the sound reproducer 230 according to the present invention are installed together in a subway station. In the event of a fire, people to be evacuated first recognize the direction of a safety zone and are evacuated through the evacuation guidance light 81, which is basic visual evacuation guidance equipment. In situations where the field of vision is short due to light smoke, the people to be evacuated may recognize the direction of the safety zone through the evacuation guidance laser 82. However, in a situation where thick smoke is generated and the field of vision is extremely short, the evacuation guidance light 81 may be useless, and in a situation where the smoke is so thick that it is difficult to open the eyes, the evacuation guidance laser 82 may not be effective. At this time, the people to be evacuated can be evacuated by intuitively recognizing the direction of the safety zone through the sound flow detected due to the evacuation guidance sound provided by the sound reproducer 230. Therefore, applying both the sound evacuation guidance function and the distribution policy for people to be evacuated, as well as the visual evacuation guidance means, can maximize the evacuation effect in a fire situation.

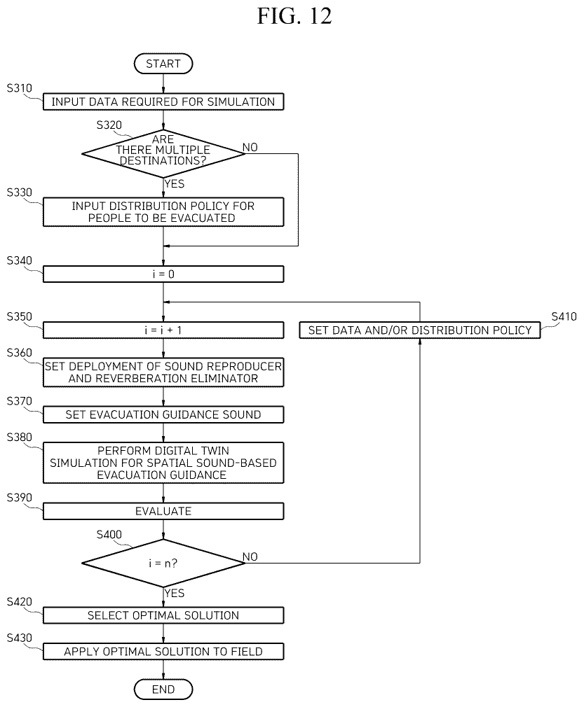

FIG. 12 is a flowchart illustrating an intelligent evacuation guidance method based on spatial sound according to one embodiment of the present invention. It is assumed that a spatial sound-based intelligent evacuation guidance method is performed by the spatial sound-based intelligent evacuation guidance system 10.

Referring to FIG. 12, the spatial sound-based intelligent evacuation guidance method according to one embodiment of the present invention may include operations S310 to S430. The spatial sound-based intelligent evacuation guidance method shown in FIG. 12 is performed according to one embodiment, and the operations of the spatial sound-based intelligent evacuation guidance method according to the present invention are not limited to the embodiment shown in FIG. 12, and they can be added to, changed, or deleted as needed.

In operation S310, data required for a simulation is received.

The input interface device 120 of the digital twin system 100 receives simulation data including the structure of a target space, the location of one or more destinations in the target space, the number of sound reproducers 230, the number of reverberation eliminators 240, and the number of virtual humans to be deployed in the virtual space obtained by modeling the target space. The simulation data may further include information on finishing materials for the walls, ceiling, and floor of the target space.

In operation S320, whether there are multiple destinations is determined. In the case of multiple destinations, operation S330 is performed, otherwise, operation S340 is performed. The processor 140 of the digital twin system 100 determines whether there are multiple destinations from the input simulation data. In the case of multiple destinations, operation S330 is performed. Otherwise, operation S340 is performed.

In operation S330, a distribution policy for people to be evacuated is input. The input interface device 120 receives the distribution policy from the user. The distribution policy for people to be evacuated may be: 1) dividing the target space into multiple zones based on the location of the destination and applying different evacuation guidance sounds according to the zones; and 2) assigning a weight to each of the multiple destinations and determining the output time or output frequency of the evacuation guidance sound directed to each destination based on the weight given to the destination.

In operation S340, the number of simulation executions is initialized.

In operation S350, the number of simulation executions is increased by one. Operation S350 is performed after operation S340 or operation S410.

In operation S360, the deployment of the sound reproducer and the reverberation eliminator is set.

The processor 140 sets the locations where the sound reproducer 230 and reverberation eliminator 240 are to be deployed in the virtual space according to predetermined criteria. For example, the processor 140 may determine the locations of the sound reproducer 230 and reverberation eliminator 240 based on a user input or a genetic algorithm.

In operation S370, evacuation guidance sound is set.

The processor 140 sets evacuation guidance sound output to be directed to the destination through the sound reproducer 230 deployed in the virtual space. The evacuation guidance sound may be configured by combining sound flows according to at least one type of linear sound flow, planar sound flow, and spatial sound flow between the plurality of sound reproducers 230.

In operation S380, a digital twin simulation for evacuation guidance based on spatial sound is performed.

The processor 140 applies the simulation data, the location of the sound reproducer 230, the location of the reverberation eliminator 240, and predetermined evacuation guidance sound to the virtual space, and performs an evacuation simulation in which the virtual human moves to the destination according to the evacuation guidance sound. The processor 140 performs the simulation after arbitrarily deploying the virtual human in the virtual space.

In the case of multiple destinations, the processor 140 performs the simulation after reflecting the distribution policy for people to be evacuated in the settings of the evacuation guidance sound.

In operation S390, the simulation results are evaluated. The processor 140 evaluates the simulation results according to predetermined evaluation criteria. The evaluation criteria may be the time when all virtual humans arrive at the destination, or, in the case of multiple destinations, the evaluation criteria may be the distribution of virtual humans for each destination at the time of completion of arrival at the destination.

In operation S400, whether the number of simulation executions reaches a predetermined maximum value n is determined. When the number of simulation executions reaches the predetermined maximum value n, operation S420 is performed, and otherwise, operation S410 is performed.

In operation S410, data and/or distribution policy for people to be evacuated is set. The processor 140 may change or maintain the previously input simulation data or distribution policy for people to be evacuated according to the user input or the settings. After operation S410, operation S350 is performed.

In operation 420, an optima solution is selected. The processor 140 evaluates the simulation results according to predetermined estimation criteria, and determines an optimal evacuation guidance sound, an optimal location of the sound reproducer 230, and an optimal location of the reverberation eliminator 240.

In operation S430, an optimal solution is applied to the field. The spatial sound generator 220 of the evacuation guidance device 200 is set to apply the evacuation guidance sound received from the digital twin system 100 to the output of the sound reproducer 230. In addition, the sound reproducer 230 and the reverberation eliminator 240 are deployed on site, either automatically or manually.

The above-described spatial sound-based intelligent evacuation guidance method has been described with reference to the flowchart presented in the drawing. For simplicity, the method has been illustrated and described as a series of blocks, but the present invention is not limited to the order of those blocks. Some blocks may occur in an order different from that shown and described herein, or simultaneously, and various other branches, flow paths, and block sequences that achieve the same or similar results may be implemented. In addition, not all blocks shown for the implementation of the method described herein may be required.

Meanwhile, in the description referring to FIG. 12, each operation may be further divided into additional operations or may be combined into fewer operations, depending on the implementation of the present invention. In addition, some operations may be omitted or the order between operations may be changed as needed. In addition, even when other omitted content, the content of FIGS. 1 to 11 can be applied to the content of FIG. 12. Additionally, the content of FIG. 12 may be applied to the content of FIGS. 1 to 11.

For reference, the components of the digital twin system 100 and the spatial sound generator 220 of the evacuation guidance device 200 according to one embodiment of the present invention may be implemented in the form of software or hardware such as a field programmable gate array (FPGA) or application specific integrated circuit (ASIC), and may perform certain roles.

However, the “components” are not limited to software or hardware, and each component may be configured to reside in an addressable storage medium or may be configured to reproduce one or more processors.

Thus, as an example, the components may include components such as software components, object-oriented software components, class components, and task components, as well as processes, functions, attributes, procedures, subroutines, segments of program code, drivers, firmware, microcode, circuits, data, databases, data structures, tables, arrays, and variables.

The components and the functions provided within those components can be combined into fewer components or divided into additional components.

At this time, it will be understood that each block of the process flowcharts described hereinbelow and combinations of the flowcharts may be performed by computer program instructions. These computer program instructions may be loaded into a processor of a generic-purpose computer, a special computer, or other programmable data processing equipment. Therefore, the instructions performed by the processor of the computer or other programmable data processing equipment may generate a means for performing functions explained in the block(s) of the flowcharts. The computer program instructions may be stored in a computer usable or computer readable memory which is directed at a computer or other programmable data processing equipment in order to implement a function in a specific method. Accordingly, the instructions stored in the computer usable or computer readable memory may produce a manufacturing item including an instruction means for performing functions explained in the block(s) of the flowcharts. The computer program instructions may be loaded on a computer or other programmable data processing equipment. Accordingly, a series of operation steps may be performed on the computer or other programmable data processing equipment to generate a process to be executed by the computer, and the instructions performing the computer or other programmable data processing equipment may provide steps for executing functions explained in the block(s) of the flowcharts.

In addition, each block may indicate a part of a module, a segment or a code including one or more executable instructions for executing a specified logical function(s). It should be noted that, in some alternative examples, functions mentioned in blocks may be performed irrespective of an order. For example, two blocks which are successively illustrated may be performed substantially at the same time, or may be performed in the inverse order according to their corresponding functions.

According to embodiments of the present invention, through spatial or sequential sound, it is possible to give directionality to the sound itself to provide an intuitive evacuation route to people to be evacuated in situations where the field of vision is short during a fire.

In addition, according to embodiments of the present invention, it is possible to intuitively design sound in various types of target spaces through spatial and acoustic digital twin technology and a virtual human-real human tester, and distribute a large number of people to be evacuated through weighted spatial acoustic space-time division.

The effects that can be obtained from the present invention are not limited to the above effects, and other effects that are not described above will be clearly understood by those who skilled in the art from the description below.

Although the present invention has been described in detail above with reference to the exemplary embodiments, those of ordinary skill in the technical field to which the present invention pertains should be able to understand that various modifications and alterations can be made without departing from the technical spirit or essential features of the present invention.

What is claimed is:

1. A digital twin system comprising:
a memory configured to store computer-readable instructions;
at least one processor configured to be implemented to execute the instructions; and
an input interface device configured to receive simulation data including a structure of a target space, locations of one or more destinations in the target space, the number of sound reproducers, the number of reverberation eliminators, and the number of virtual humans to be deployed in a virtual space obtained by modeling the target space,
wherein the at least one processor executes the instructions to:
set locations where the sound reproducer and the reverberation eliminator are to be deployed in the virtual space according to predetermined criteria;
set an evacuation guidance sound output to be directed to the destination through the sound reproducer disposed in the virtual space;
apply the simulation data, the location of the sound reproducer, the location of the reverberation eliminator, and the evacuation guidance sound to the virtual space to perform a simulation in which the virtual human is evacuated to the destination according to the evacuation guidance sound; and
evaluate a result of the simulation according to predetermined evaluation criteria to determine the location of the sound reproducer and the location of the reverberation eliminator.

2. The digital twin system of claim 1, wherein the simulation data further includes information on finishing materials for a wall, a ceiling, and a floor of the target space.

3. The digital twin system of claim 1, wherein the at least one randomly deploys the virtual human in the virtual space and then performs the simulation.

4. The digital twin system of claim 1, wherein the evaluation criteria includes a time at which all the virtual humans arrive at the destination.

5. The digital twin system of claim 1, wherein the at least one processor determines whether there are a plurality of destinations,
the input interface device receives a predetermined distribution policy for a person to be evacuated in the case of the plurality of destinations, and
the at least one processor reflects the distribution policy for the person to be evacuated when the evacuation guidance sound is set and then perform the simulation.

6. The digital twin system of claim 5, wherein, in the distribution policy for the person to be evacuated, the target space is divided into a plurality of zones based on the location of the destination, and different evacuation guidance sounds are applied according to the zones.

7. The digital twin system of claim 5, wherein, in the distribution policy for the person to be evacuated, a weight is assigned to each of the plurality of destinations, and an output time of the evacuation guidance sound directed to each of the destinations is determined based on the weight.

8. The digital twin system of claim 5, wherein, in the distribution policy for the person to be evacuated, a weight is assigned to each of the plurality of destinations, and an output frequency of the evacuation guidance sound directed to each of the destinations is determined based on the weight.

9. The digital twin system of claim 1, wherein the evacuation guidance sound is configured by combining sound flows according to at least one type of linear sound flow, planar sound flow, and spatial sound flow between a plurality of sound reproducers.

10. The digital twin system of claim 1, wherein the at least one processor is configured to:
perform the simulation a plurality of times; and
change the locations of the sound reproducer and the reverberation eliminator before performing the simulation.

11. A spatial sound-based intelligent evacuation guidance method comprising:
receiving, by a digital twin system, simulation data including a structure of a target space, locations of one or more destinations in the target space, the number of sound reproducers, the number of reverberation eliminators, and the number of virtual humans to be deployed in a virtual space obtained by modeling the target space;
setting, by the digital twin system, locations where the sound reproducer and the reverberation eliminator are to be deployed in the virtual space according to predetermined criteria;
setting, by the digital twin system, an evacuation guidance sound output to be directed to the destination through the sound reproducer disposed in the virtual space;
applying, by the digital twin system, the simulation data, the location of the sound reproducer, the location of the reverberation eliminator, and the evacuation guidance sound to the virtual space to perform a simulation in which the virtual human is evacuated to the destination according to the evacuation guidance sound; and
evaluating, by the digital twin system, the result of the simulation according to predetermined evaluation criteria to determine the location of the sound reproducer and the location of the reverberation eliminator.

12. The intelligent evacuation guidance method of claim 11, wherein the simulation data further includes information on finishing materials for a wall, a ceiling, and a floor of the target space.

13. The intelligent evacuation guidance method of claim 11, wherein the performing of the simulation includes randomly deploying, by the digital twin system, the virtual human in the virtual space, and then performing the simulation.

14. The intelligent evacuation guidance method of claim 11, wherein the evaluation criteria includes a time at which all the virtual humans arrive at the destination.

15. The intelligent evacuation guidance method of claim 11, further comprising:
determining, by the digital twin system, whether there are a plurality of destinations; and
receiving, in the case of the plurality of destinations, a predetermined distribution policy for a person to be evacuated,
wherein the performing of the simulation further includes performing the simulation after reflecting the distribution policy for the person to be evacuated in the setting of the evacuation guidance sound.

16. The intelligent evacuation guidance method of claim 15, wherein, in the distribution policy for the person to be evacuated, the target space is divided into a plurality of zones based on the location of the destination, and different evacuation guidance sounds are applied according to the zones.

17. The intelligent evacuation guidance method of claim 15, wherein, in the distribution policy for the person to be evacuated, a weight is assigned to each of the plurality of destinations, and an output time of the evacuation guidance sound directed to each of the destinations is determined based on the weight.

18. The intelligent evacuation guidance method of claim 15, wherein, in the distribution policy for the person to be evacuated, a weight is assigned to each of the plurality of destinations, and an output frequency of the evacuation guidance sound directed to each of the destinations is determined based on the weight.

19. The intelligent evacuation guidance method of claim 11, wherein the evacuation guidance sound is configured by combining sound flows according to at least one type of linear sound flow, planar sound flow, and spatial sound flow between a plurality of sound reproducers.

20. The intelligent evacuation guidance method of claim 11, wherein the performing of the simulation is performed a plurality of times, and
the method further comprising changing, by the digital twin system, the locations of the sound reproducer and the reverberation eliminator.
